(19) United States
(12) Patent Application Publication
(10) Pub. No.: US 2026/0075866 A1
(43) Pub. Date: Mar. 12, 2026

(54) SEMICONDUCTOR DEVICE

(71) Applicant: Ancora Semiconductors Inc., Taoyuan City (TW)

(72) Inventors: Li-Fan LIN, Taoyuan City (TW); Ying-Chen LIU, Taoyuan City (TW)

(21) Appl. No.: 19/220,083

(22) Filed: May 28, 2025

Related U.S. Application Data
(63) Continuation-in-part of application No. 18/830,558, filed on Sep. 10, 2024.

(51) Int. Cl. H10D 30/47; H10D 62/85; H10D 64/00

(52) U.S. Cl. CPC H10D 30/475; H10D 62/8503; H10D 64/112

(57) ABSTRACT

A semiconductor device includes an active layer having an active region, a source electrode, a drain electrode, and a gate electrode disposed on the active region of the active layer and extending along a first direction, multiple P—GaN islands disposed on the active region and under the drain electrode, and multiple insulating islands disposed between the P—GaN islands and the drain electrode.

### CROSS-REFERENCE TO RELATED APPLICATION

This application is a Continuation-in-part of U.S. application Ser. No. 18/830,558, filed on Sep. 10, 2024, the entirety of which is incorporated by reference herein in their entireties.

### BACKGROUND

### Field of Disclosure

The present disclosure relates to a semiconductor device.

### Description of Related Art

A power semiconductor device is used as a switch under high pressure. The on-state resistance gradually becomes larger after being used more times. Thus, there is a need to provide a semiconductor device that may solve the problem mentioned above.

### SUMMARY

A semiconductor device includes an active layer having an active region, a source electrode, a drain electrode, and a gate electrode disposed on the active region of the active layer and extending along a first direction, multiple P—GaN islands disposed on the active region and under the drain electrode, and multiple insulating islands disposed between the P—GaN islands and the drain electrode.

A semiconductor device includes an active layer having an active region, a source electrode, a drain electrode, and a gate electrode disposed on the active region of the active layer. The source electrode, the drain electrode, and the gate electrode extend along a first direction. Multiple P—GaN islands disposed on the active region and under the drain electrode. Each of the P—GaN islands includes a first portion and a second portion, and the drain electrode is at least located between the first portion and the second portion of the P—GaN islands respectively.

In the aforementioned embodiments, the P—GaN islands are used as hole injection layers to absorb the trapped charges in the drain electrode. Therefore, the semiconductor device of the present disclosure can reduce on-state resistance by disposing P—GaN islands under the drain electrode. The insulating islands can increase a voltage difference between the drain electrode and the P—GaN islands, such that the hole injection quality can be enhanced. When the P—GaN islands includes a first portion and a second portion. The drain electrode is at least located between the first portion and the second portion and in contact with the substrate. With such configuration, the ohmic metal of the drain electrode is electrically to the AlGaN or GaN material below the P—GaN islands. As such, the electrical current area is increased, and therefore the electrical resistance can be reduced.

### BRIEF DESCRIPTION OF THE DRAWINGS

FIG. 1 is a top view of a semiconductor device according to some embodiments of the present disclosure.

FIG. 2 is a cross-sectional view along line 2-2 of FIG. 1.

FIG. 3A is a partial top view of the semiconductor device omitting the first drain metal layers, the second source metal layer, the second drain metal layer, the source pad, and the drain pad.

FIG. 3B is a partial top view of the semiconductor device omitting the second source metal layer, the second drain metal layer, the source pad, and the drain pad according to one embodiment of the present disclosure.

FIG. 4 is a cross-sectional view of a semiconductor device according to one embodiment of the present disclosure.

FIG. 5 is a cross-sectional view of a semiconductor device according to one embodiment of the present disclosure.

FIG. 6A is a partial top view of the semiconductor device omitting the first drain metal layers, the second source metal layer, the second drain metal layer, the source pad, and the drain pad.

FIG. 6B is a partial top view of the semiconductor device omitting the first drain metal layers, the second source metal layer, the second drain metal layer, the source pad, and the drain pad according to one embodiment of the present disclosure.

FIG. 7 is a cross-sectional view of a semiconductor device according to one embodiment of the present disclosure.

FIG. 8 is a cross-sectional view of a semiconductor device according to one embodiment of the present disclosure.

FIG. 9 is a top view of a semiconductor device according to one embodiment of the present disclosure.

FIG. 10 is a cross-sectional view of a semiconductor device according to one embodiment of the present disclosure.

FIG. 11A is a partial top view of the semiconductor device omitting the first drain metal layers, the second source metal layer, the second drain metal layer, the source pad, and the drain pad.

FIG. 11B is a partial top view of the semiconductor device omitting the first drain metal layers, the second source metal layer, the second drain metal layer, the source pad, and the drain pad according to one embodiment of the present disclosure.

FIG. 12 is a cross-sectional view of a semiconductor device according to one embodiment of the present disclosure.

FIG. 13A is a partial top view of the semiconductor device omitting the first drain metal layers, the second source metal layer, the second drain metal layer, the source pad, and the drain pad.

FIG. 13B is a partial top view of the semiconductor device omitting the first drain metal layers, the second source metal layer, the second drain metal layer, the source pad, and the drain pad according to one embodiment of the present disclosure.

FIG. 14 is a cross-sectional view of a semiconductor device according to one embodiment of the present disclosure.

FIG. 15 is a cross-sectional view of a semiconductor device according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

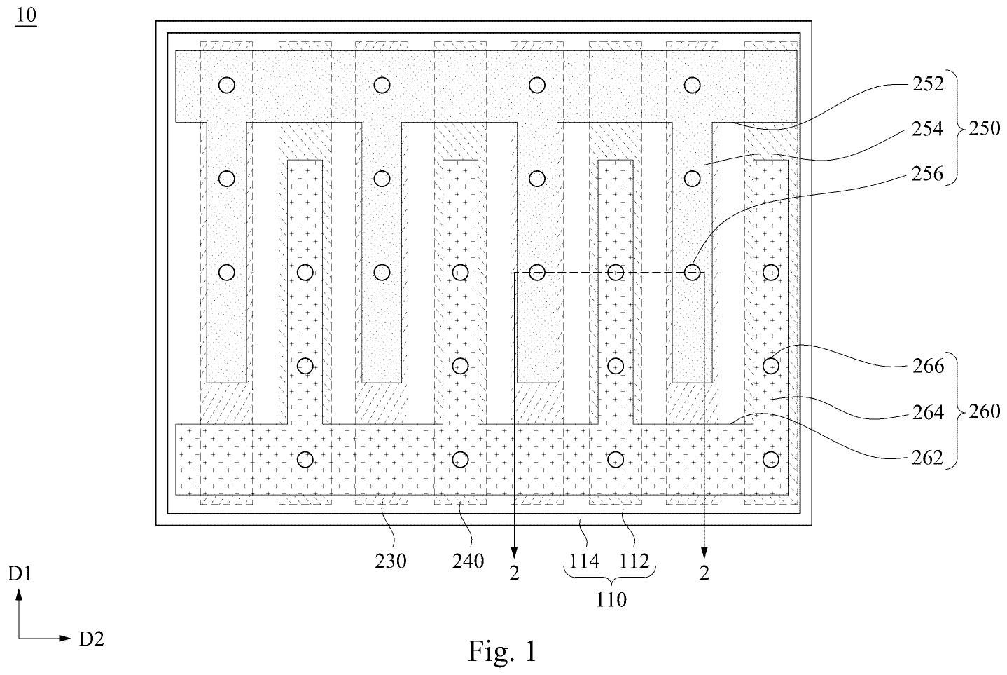

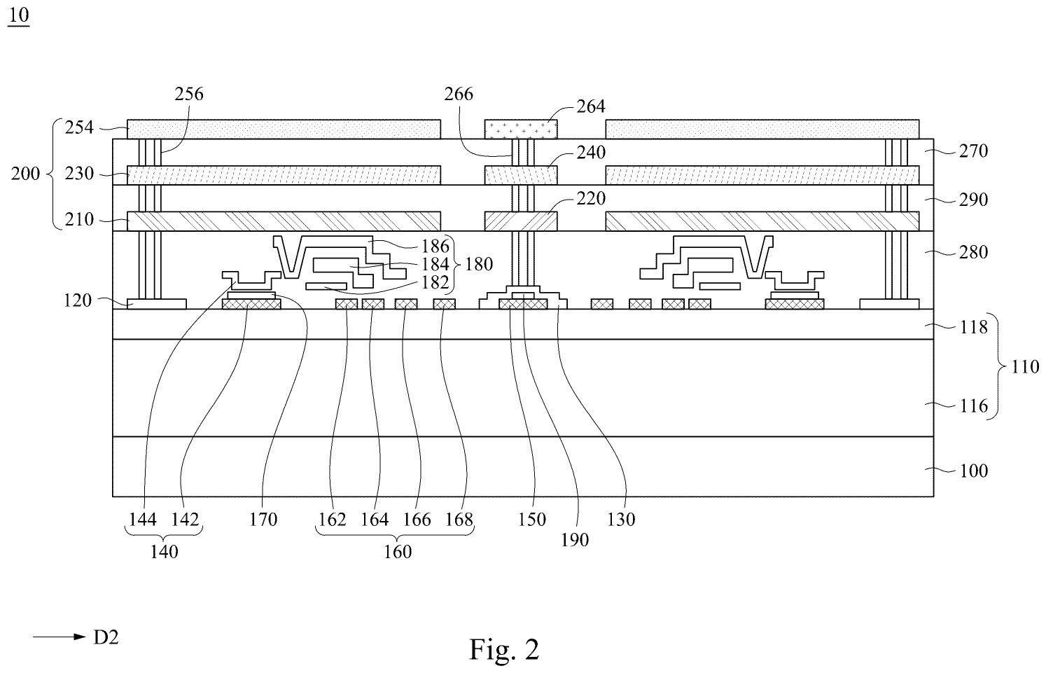

FIG. 1 is a top view of a semiconductor device 10 according to some embodiments of the present disclosure. FIG. 2 is a cross-sectional view along line 2-2 of FIG. 1. Reference is made to FIG. 1 and FIG. 2. The semiconductor device 10 includes an active layer 110, a source electrode 120, a drain electrode 130, a gate electrode 140, multiple first P—GaN islands 150, multiple second P—GaN islands 160, multiple ohmic metal islands 170, multiple field plates 180, and multiple insulating islands 190 disposed between the drain electrode 130 and the first P—GaN islands 150.

Reference is made to FIG. 1 and FIG. 2. The active layer 110 includes a channel layer 116 and a barrier layer 118 disposed on the channel layer 116. The active layer 110 has an active region 112. In some embodiments, the channel layer 116 can be made of GaN, and the barrier layer 118 can be made of AlGaN or other III-V material. The active layer 110 further includes an insulating region 114 surrounding the active region 112. The insulating region 114 may be formed by implanting ions, such as oxygen, nitrogen, carbon, or the like, into the active layer 110. In some other embodiments, the insulating region 114 is a shallow trench isolation (STI). The active layer 110 may be selectively disposed

### On a Substrate 100.

Reference is made to FIG. 1 and FIG. 2. The source electrodes 120, the drain electrodes 130, the gate electrodes 140 are disposed on the active region 112 of the active layer 110 and extend along a first direction D1. The semiconductor device 10 further includes multiple metal layers 200. The metal layers includes a first source metal layer 210 disposed above the source electrode 120 and/or the gate electrode 140, a first drain metal layer 220 disposed above the drain electrode 130, a second source metal layer 230 disposed above the first source metal layer 210, a second drain metal layer 240 disposed above the first drain metal layer 220, a source pad 250, and a drain pad 260. In some other embodiments, the semiconductor device has no second source metal layer and the second drain metal layer.

Reference is made to FIG. 1 and FIG. 2. The first source metal layer 210 is electrically connected to the source electrode 120. The first drain metal layer 220 is electrically connected to the drain electrode 130. The second source metal layer 230 is electrically connected to the first source metal layer 210. The second drain metal layer 240 is electrically connected to the first drain metal layer 220. The source pad 250 is electrically connected to the second source metal layer 230, and the drain pad 260 is electrically connected to the second drain metal layer 240.

In the present embodiment, the first source metal layers 210, the first drain metal layers 220, the second source metal layers 230, and the second drain metal layers 240 extend along the first direction D1. The body portion 252 of the source pad 250 and the body portion 262 of the drain pad 260 extend along the second direction D2. The branch portions 254 of the source pad 250 and the branch portions 264 of the drain pad 260 extend along the first direction D1.

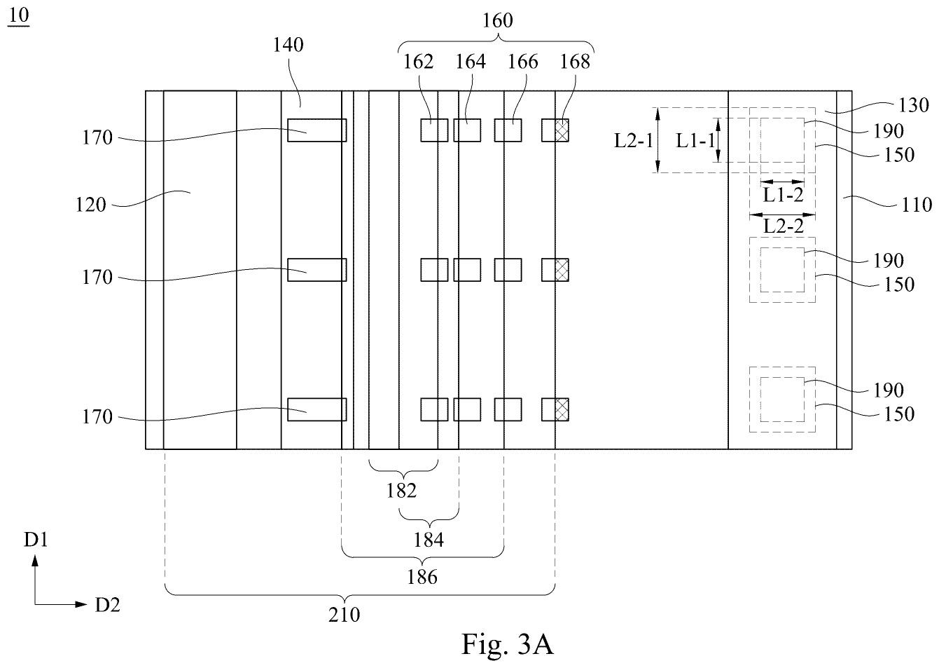

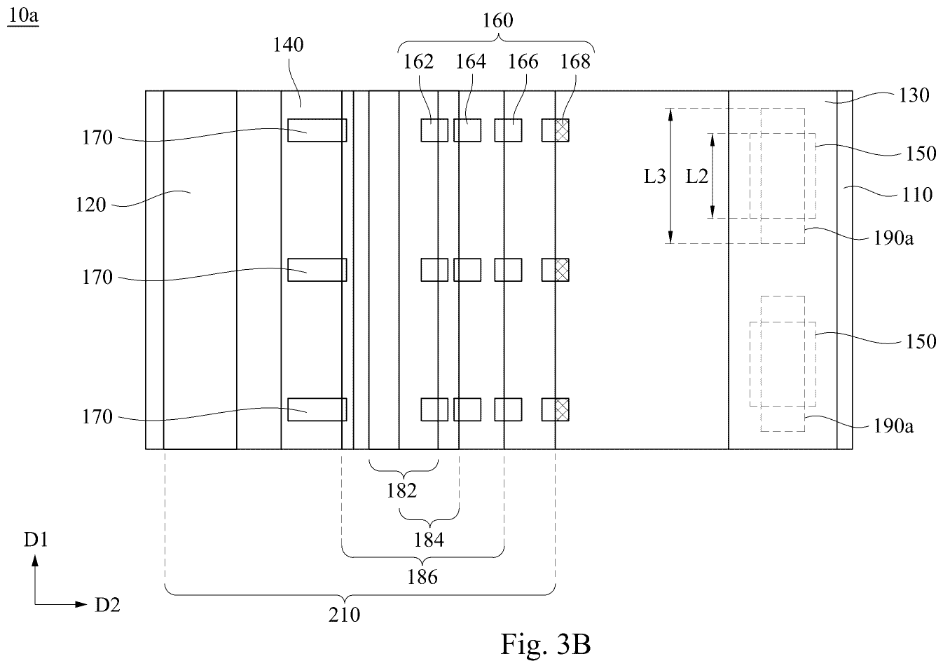

FIG. 3A is a partial top view of the semiconductor device 10 omitting the first drain metal layers, the second source metal layer, the second drain metal layer, the source pad, and the drain pad. The first P—GaN islands 150 are disposed on the active region 112 and under the drain electrode 130. The first P—GaN islands 150 are arranged along the first direction D1. The source electrode 120 and the drain electrode 130 extend along the first direction D1.

In the present disclosure, a first length L1-1 of each of the insulating islands 190 along the first direction D1 is shorter than a second length L2-1 of each of the first P—GaN islands 150 along the first direction D1. Another first length L1-2 of each of the insulating islands 190 along the second direction D2 is shorter than another second length L2-2 of each of the first P—GaN islands 150 along the second direction D2. In other words, a vertical projection of each of the first P—GaN islands 150 on the active region 112 fully encompasses a vertical projection of the insulating islands 190 on the active region 112.

In the present embodiment, a vertical projection of the drain electrode 130 on the active region 112 fully encompasses the vertical projection of each of the first P—GaN islands 150 on the active region 112. The vertical projection of the drain electrode 130 on the active region 112 fully encompasses the vertical projection of each of the insulating islands 190 on the active region 112. A sidewall of each of the first P—GaN islands 150 are surrounded by the drain electrode 130, but the present disclosure is not limited thereto.

Reference is made to FIG. 2 and FIG. 3A. The gate electrode 140 includes a gate P—GaN layer 142 and a schottky metal layer 144 above the gate P—GaN layer 142. The gate P—GaN layer 142 and the schottky metal layer 144 both extend along the first direction D1. The ohmic metal islands 170 are disposed between the gate P—GaN layer 142 and the schottky metal layer 144, and are arranged along the first direction D1. The material of the ohmic metal islands is the same as the drain electrode 130 and the source electrode 120. In some other embodiments, only an ohmic metal layer extends along the first direction D1 and is disposed on a gate P—GaN layer, and there is no schottky metal layer.

Charges are trapped in the regions under and surrounding the drain electrode 130 and at the interface between the first P—GaN islands 150 and the barrier layer 118 after usage, and therefore the on-state resistance of the semiconductor device 10 becomes larger. The first P—GaN islands 150 are used as hole injection layers to neutralize the trapped charges in the regions described above. Therefore, the on-state resistance can be reduced by disposing the first P—GaN islands 150 between the active layer 110 and the drain electrode 130. The insulating islands 190 can increase a voltage difference between the drain electrode 130 and the first P—GaN islands 150, such that the hole injection quality can be enhanced.

Reference is made to FIG. 2 and FIG. 3A. Multiple field plates 180 are disposed between the source electrode 120 and the drain electrode 130 and on the active region 112. The field plates 180 extend along the first direction D1. The second P—GaN islands 160 disposed on the active region 112 and under the field plates 180. The second P—GaN islands 160 are arranged along the first direction D1 and the second direction D2.

The field plates 180 includes a second field plate 184, a first field plate 182 covered by the second field plate 184, and a third field plate 186 covering the first field plate 182, the second field plate 184. The second field plate 184 and the schottky metal layer 144 of the gate electrode 140 are formed as the same layer.

The second P—GaN islands 160 include a first column 162, a second column 164, a third column 166, and a fourth column 168. The first column 162 is located between the gate electrode 140 and the second column 164. The first column 162 and an edge of the first field plate 182 have an overlapping region in the plan view. The second column 164 is located between the first column 162 and the third column 166. The second column 164 and an edge of the second field plate 184 have an overlapping region in the plan view. The third column 166 is located between the second column 164 and the fourth column 168. The third column 166 and an edge of the third field plate 186 have an overlapping region in the plan view. The fourth column 168 is located between the third column 166 and the first P—GaN islands 150. The fourth column 168 and an edge of the first source metal layer 210 have an overlapping region in the plan view.

The second P—GaN islands 160 are used as hole injection layers to neutralize the trapped charges in the regions under and surrounding the field plates 180. Therefore, the on-state resistance can be reduced by disposing the second P—GaN islands 160 between the active layer 110 and the field plates 180.

The ohmic metal islands 170 are used as hole injection layers to absorb the trapped charges in the regions under and surrounding the gate electrode 140. Therefore, the on-state resistance can be reduced by disposing the ohmic metal islands 170 between the gate P—GaN layer 142 and the schottky metal layer 144 of the gate electrode 140.

The semiconductor device 10 further includes a dielectric layer 270. The dielectric layer 270 covers the second source metal layers 230 and the second drain metal layers 240. The source pad 250 and the drain pad 260 are disposed on the dielectric layer 270. The source pad 250 is electrically connected to the second source metal layers 230 through vias 256 disposed in the dielectric layer 270. The drain pad 260 is electrically connected to the second drain metal layers 240 through vias 266 disposed in the dielectric layer 270.

The semiconductor device 10 further includes dielectric layers 280 and 290. The dielectric layer 280 is disposed on the active layer 110. The dielectric layer 280 covers the source electrode 120, the drain electrode 130, and the gate electrodes 140. The first source metal layers 210 are disposed on the dielectric layer 280 and cover the source electrode 120 and/or the gate electrodes 140, and the first drain metal layers 220 are disposed on the dielectric layer 280 and cover the drain electrode 130.

The dielectric layer 290 covers the first source metal layers 210 and the first drain metal layers 220. In other words, the first source metal layers 210 and the first drain metal layers 220 are disposed between the dielectric layers 290 and 280, and the second source metal layers 230 and the second drain metal layers 240 are disposed between the dielectric layers 290 and 270. The second source metal layers 230 are disposed on the dielectric layer 290 and are electrically connected to the first source metal layers 210 through vias 232 disposed in the dielectric layer 290. The second drain metal layers 240 are disposed on the dielectric layer 290 and are electrically connected to the first drain metal layers 220 through vias 242 disposed in the dielectric layer 290.

FIG. 3B is a partial top view of the semiconductor device 10a omitting the first drain metal layer, the second source metal layer, the second drain metal layer, the source pad, and the drain pad according to one embodiment of the present disclosure. The semiconductor device 10a is similar to the semiconductor device 10 shown in FIG. 3A. The difference is that the third length L3 of each of the insulating islands 190a along the first direction D1 is longer than the second length L2 of each of the first P—GaN islands 150 along the first direction D1. The semiconductor device 10a and the semiconductor device 10 shown in FIG. 2 have the same advantages, and therefore the description is not repeated hereinafter.

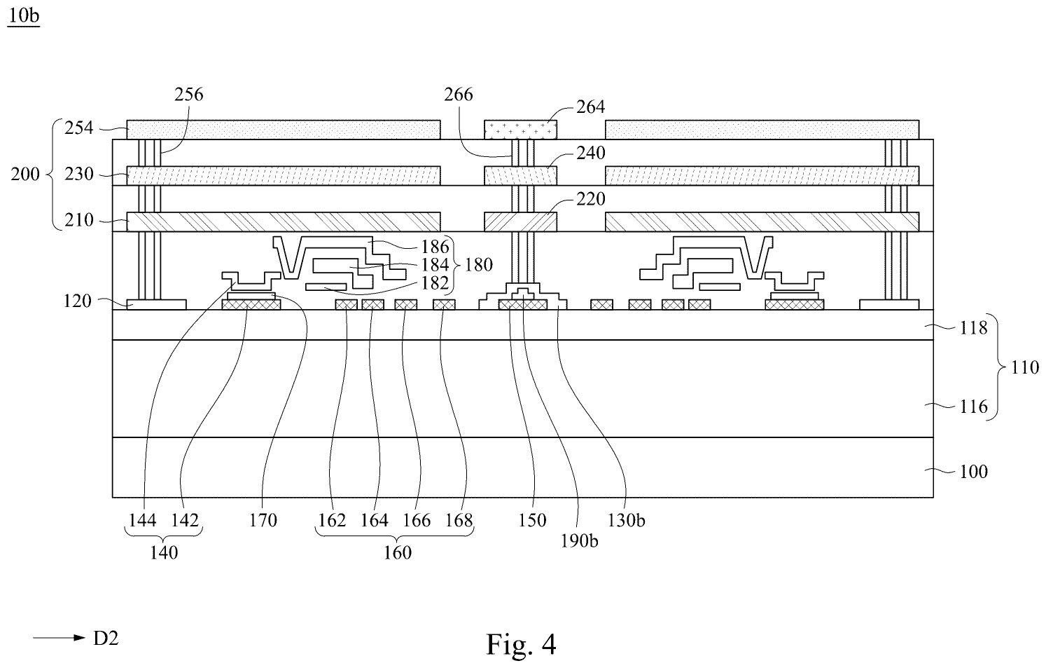

FIG. 4 is a cross-sectional view of a semiconductor device 10b according to one embodiment of the present disclosure. The semiconductor device 10b is similar to the semiconductor device 10 shown in FIG. 2. The difference is that the insulating islands 190b in a cross-sectional view have a stepped shape. In some other embodiments, the stepped shape of the insulating islands 190b in a cross-sectional view can be an inclined step. The semiconductor device 10b and the semiconductor device 10 shown in FIG. 2 have the same advantages, and therefore the description is not repeated hereinafter.

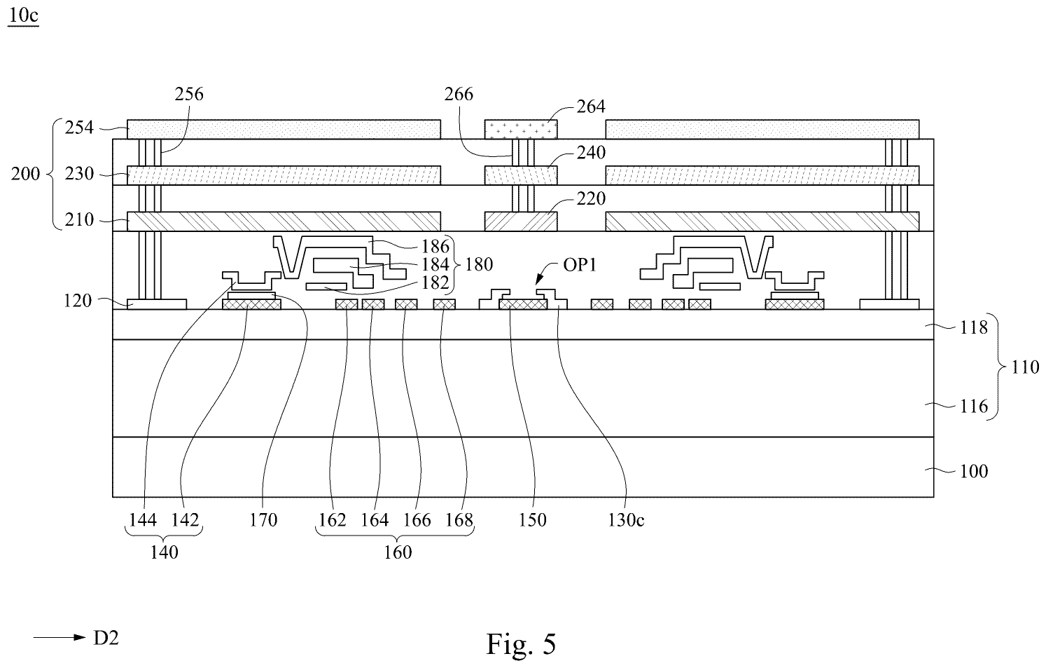

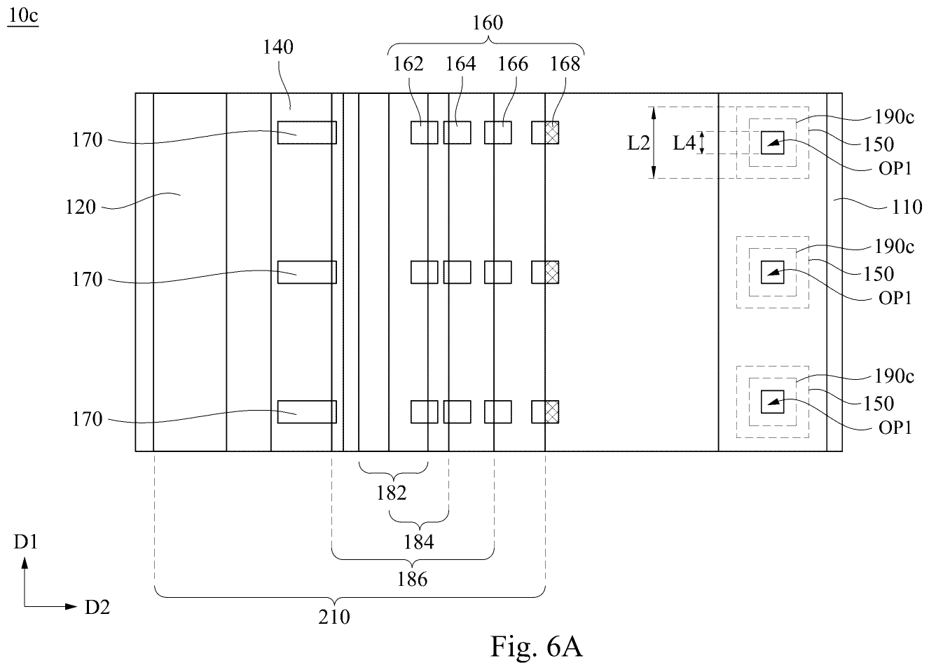

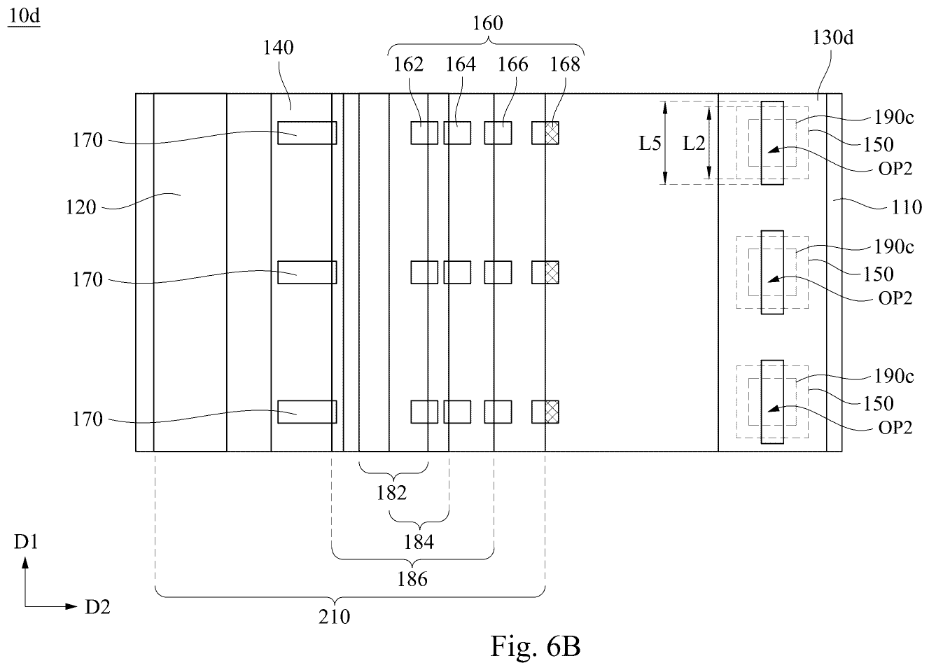

FIG. 5 is a cross-sectional view of a semiconductor device 10c according to one embodiment of the present disclosure. FIG. 6A is a partial top view of the semiconductor device 10c omitting the first drain metal layers, the second source metal layer, the second drain metal layer, the source pad, and the drain pad. The semiconductor device 10c is similar to the semiconductor device 10 shown in FIG. 2. The difference is that the drain electrode 130c has a first opening OP1, and the insulating islands 190c are exposed from the first opening OP1. In the present embodiment, a fourth length L4 of the first opening OP1 along the first direction D1 is shorter than the second length L2 of each of the first P—GaN islands 150 along the first direction D1. In other embodiments, the configuration of the insulating islands 190c can be the same as the insulating islands 190a shown in FIG. 3B. The semiconductor device 10c and the semiconductor device 10 shown in FIG. 2 have the same advantages, and therefore the description is not repeated hereinafter.

FIG. 6B is a partial top view of the semiconductor device 10d omitting the first drain metal layers, the second source metal layer, the second drain metal layer, the source pad, and the drain pad according to one embodiment of the present disclosure. The semiconductor device 10d is similar to the semiconductor device 10c shown in FIG. 6A. The difference is that the fifth length L5 of the second opening OP2 of the drain electrode 130d along the first direction D1 is longer than the second length L2 of each of the first P—GaN islands 150 along the first direction D1. In other embodiments, the configuration of the insulating islands 190c can be the same as the insulating islands 190a shown in FIG. 3B. The semiconductor device 10d and the semiconductor device 10c shown in FIG. 6A have the same advantages, and therefore the description is not repeated hereinafter.

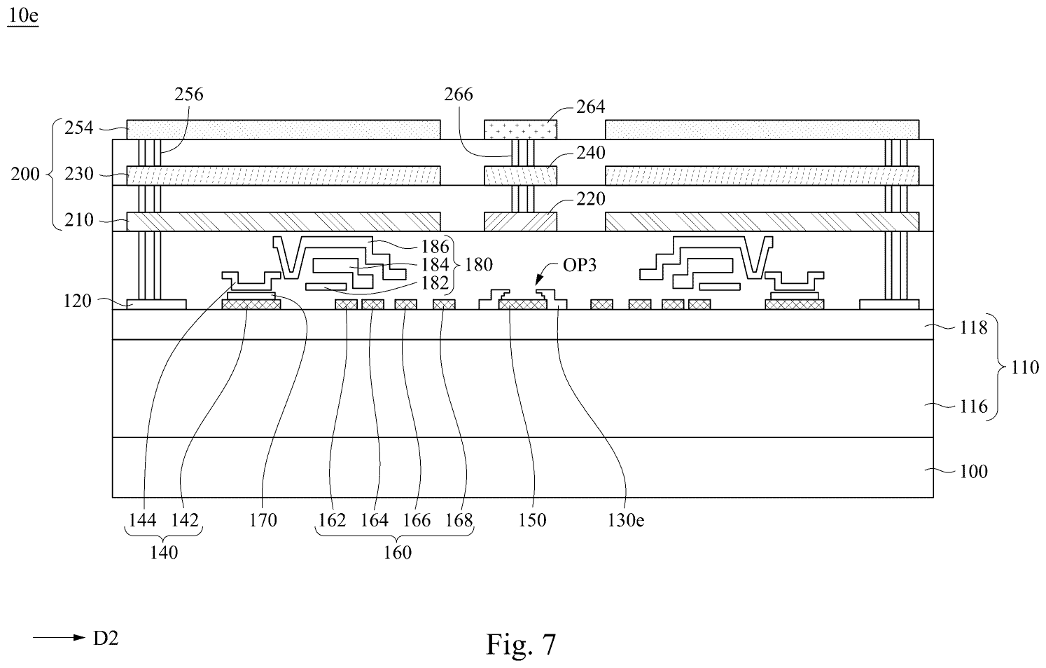

FIG. 7 is a cross-sectional view of a semiconductor device 10e according to one embodiment of the present disclosure. The semiconductor device 10e is similar to the semiconductor device 10c shown in FIG. 5. The difference is that the semiconductor device 10e has the insulating islands 190e and a profile of the third opening OP3 of the drain electrode 130e in a cross-sectional view has a stepped shape. In some other embodiments, the stepped shape of the profile of the third opening OP3 in a cross-sectional view can be an inclined step. The semiconductor device 10e and the semiconductor device 10c shown in FIG. 5 have the same advantages, and therefore the description is not repeated hereinafter.

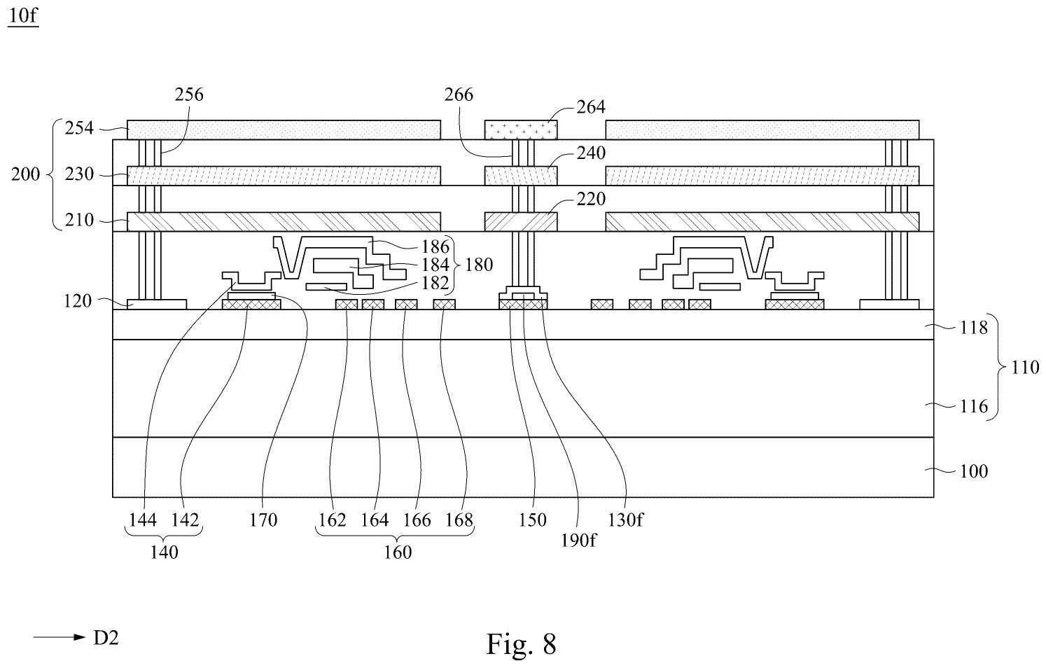

FIG. 8 is a cross-sectional view of a semiconductor device 10f according to one embodiment of the present disclosure. The semiconductor device 10f is similar to the semiconductor device 10 shown in FIG. 2. The difference is that the sidewalls of the first P—GaN islands 150 are not surrounded by the drain electrode 130f. The sidewalls of the insulating islands 190f are surrounded by the drain electrode 130f. The semiconductor device 10f and the semiconductor device 10 shown in FIG. 2 have the same advantages, and therefore the description is not repeated hereinafter.

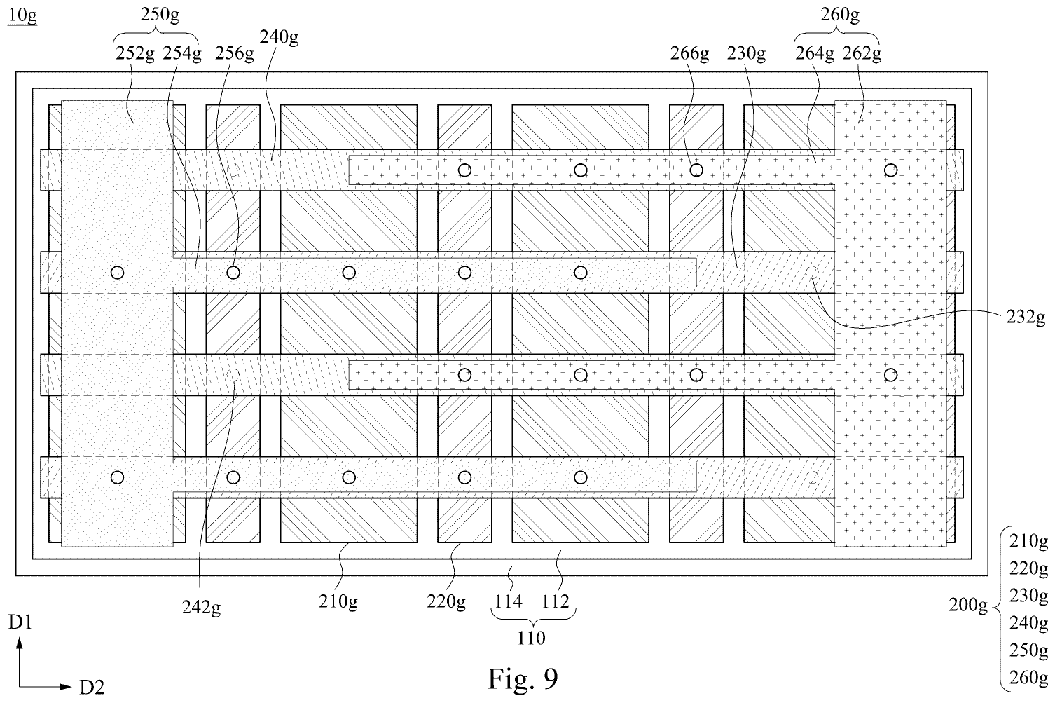

FIG. 9 is a top view of a semiconductor device 10g according to one embodiment of the present disclosure. The semiconductor device 10g is similar to the semiconductor device 10 shown in FIG. 1. The difference is the configuration of the metal layers 200g. In the present embodiment, the first source metal layer 210g and the first drain metal layer 220g extend along the first direction D1. The second source metal layer 230g and the second drain metal layer 240g extend along the second direction D2. The source pad 250g includes a body portion 252g extending along the first direction D1 and multiple branch portions 254g extending along the second direction D2. The drain pad 260g includes a body portion 262g extending along the first direction D1 and multiple branch portions 264g extending along the second direction D2. The semiconductor device 10g and the semiconductor device 10 shown in FIG. 1 have the same advantages, and therefore the description is not repeated hereinafter.

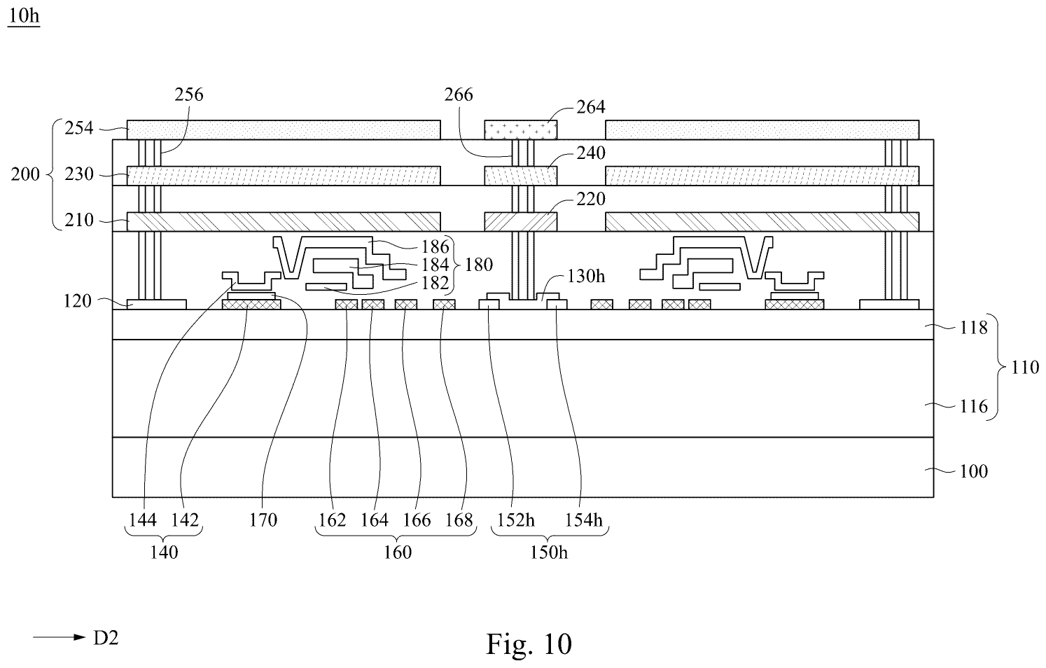

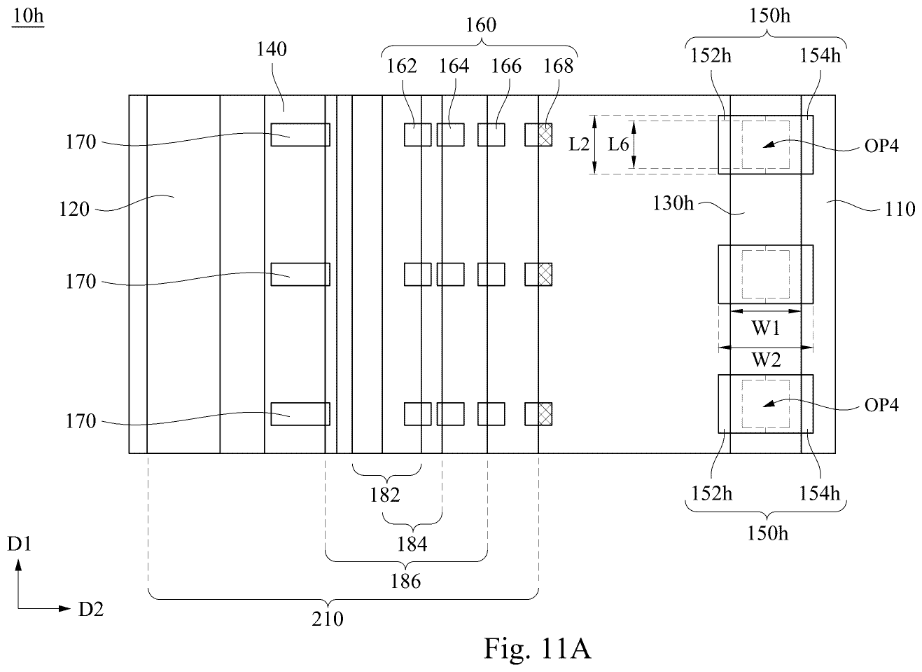

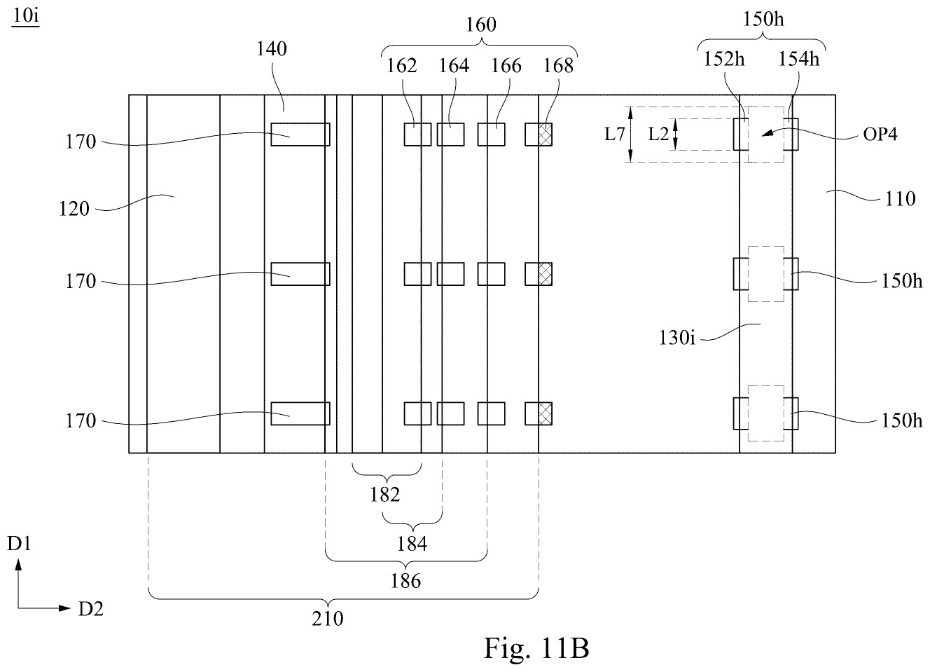

FIG. 10 is a cross-sectional view of a semiconductor device 10h according to one embodiment of the present disclosure. FIG. 11A is a partial top view of the semiconductor device 10h omitting the first drain metal layers, the second source metal layer, the second drain metal layer, the source pad, and the drain pad. The semiconductor device 10h is similar to the semiconductor device 10 shown in FIG. 2, and the difference is the configuration of the drain electrode 130h and the first P—GaN islands 150h. The semiconductor device 10h includes multiple drain electrodes 130h arranged along the first direction D1. Each of the first P—GaN islands 150h includes a first portion 152h and a second portion 154h. The drain electrodes 130h are at least located between the first portion 152h and the second portion 154h of the first P—GaN islands 150h respectively and in contact with the substrate 100.

In the present embodiment, the first portion 152h and the second portion 154h of the first P—GaN islands 150h are partially connected to form a fourth opening OP4, and the drain electrodes 130h are at least located in the fourth openings OP4 of the first P—GaN islands 150h respectively. With such configuration, the ohmic metal of the drain electrodes 130h are electrically connected to the AlGaN or GaN material below the first P—GaN islands 150h. As such, the electrical current area is increased, and the electrical resistance can be reduced. In some other embodiments, the first portions and the second portions of the first P—GaN islands are spaced apart from each other.

In the present embodiment, the drain electrodes 130h are partially disposed above the first P—GaN islands 150h respectively. A sixth length L6 of each of the fourth openings OP4 along the first direction D1 is shorter than the second length L2 of each of the first P—GaN islands 150h along the first direction D1 respectively. A first width W1 of the drain electrode 130h along the second direction D2 perpendicular to the first direction D1 is shorter than a second width W2 of each of the first P—GaN islands 150h along the second direction D2.

FIG. 11B is a partial top view of the semiconductor device 10i omitting the first drain metal layers, the second source metal layer, the second drain metal layer, the source pad, and the drain pad according to one embodiment of the present disclosure. The semiconductor device 10i is similar to the semiconductor device 10h shown in FIG. 11A. The difference is that the seventh length L7 of each of the fourth openings OP4 along the first direction D1 is longer than the second length L2 of each of the first P—GaN islands 150h along the first direction D1 respectively. The semiconductor device 10i and the semiconductor device 10h shown in FIG. 10 have the same advantages, and therefore the description is not repeated hereinafter.

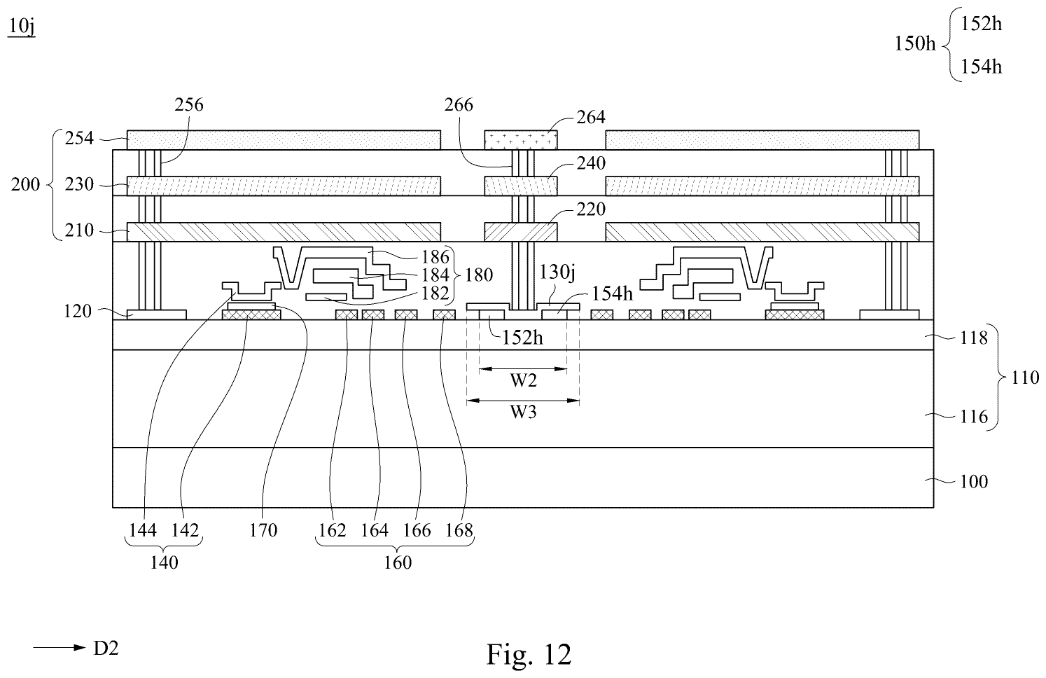

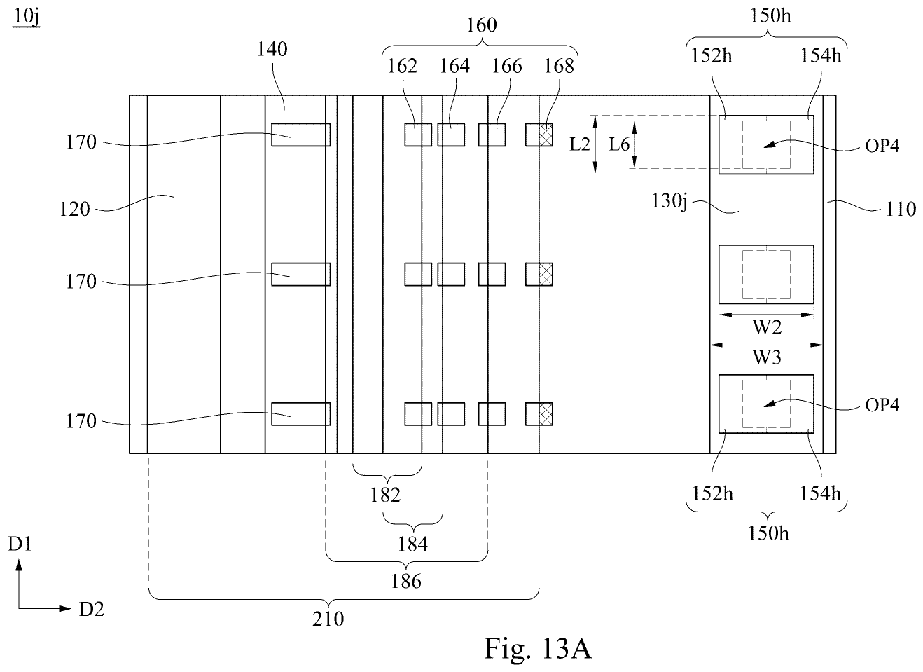

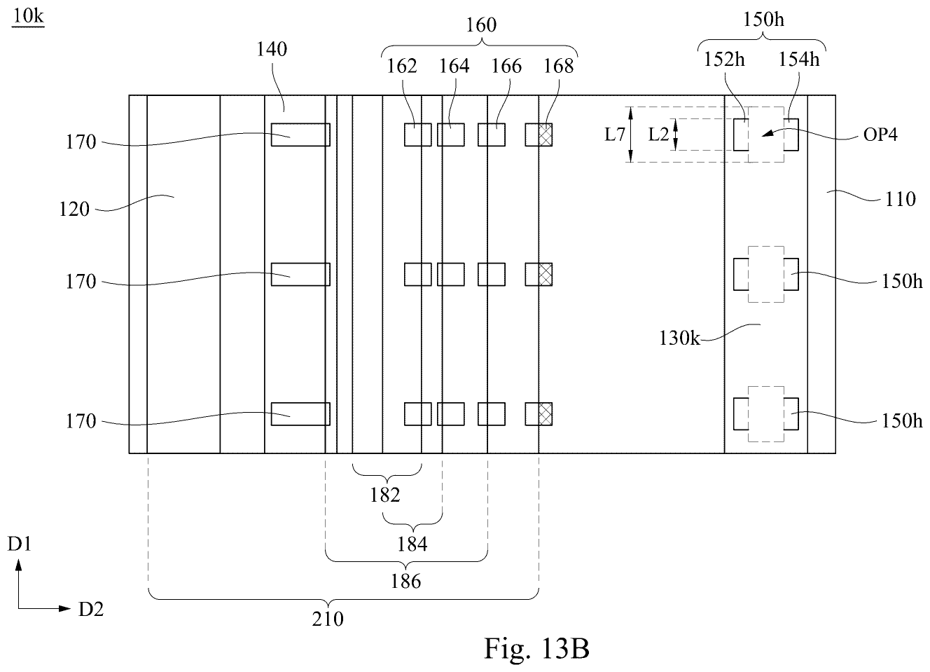

FIG. 12 is a cross-sectional view of a semiconductor device 10j according to one embodiment of the present disclosure. FIG. 13A is a partial top view of the semiconductor device 10j omitting the first drain metal layers, the second source metal layer, the second drain metal layer, the source pad, and the drain pad. The semiconductor device 10j is similar to the semiconductor device 10h shown in FIG. 10 and FIG. 11A, and the difference is the a third width W3 of the drain electrode 130j along the second direction D2 is longer than the second width W2 of each of the first P—GaN islands 150h along the second direction D2. The semiconductor device 10j and the semiconductor device 10h shown in FIG. 10 have the same advantages, and therefore the description is not repeated hereinafter.

FIG. 13B is a partial top view of the semiconductor device 10k omitting the first drain metal layers, the second source metal layer, the second drain metal layer, the source pad, and the drain pad according to one embodiment of the present disclosure. The semiconductor device 10k is similar to the semiconductor device 10j shown in FIG. 13A. The difference is that the seventh length L7 of each of the fourth openings OP4 along the first direction D1 is longer than the second length L2 of each of the first P—GaN islands 150h along the first direction D1 respectively. The semiconductor device 10k and the semiconductor device 10j shown in FIG. 12 and FIG. 13A have the same advantages, and therefore the description is not repeated hereinafter.

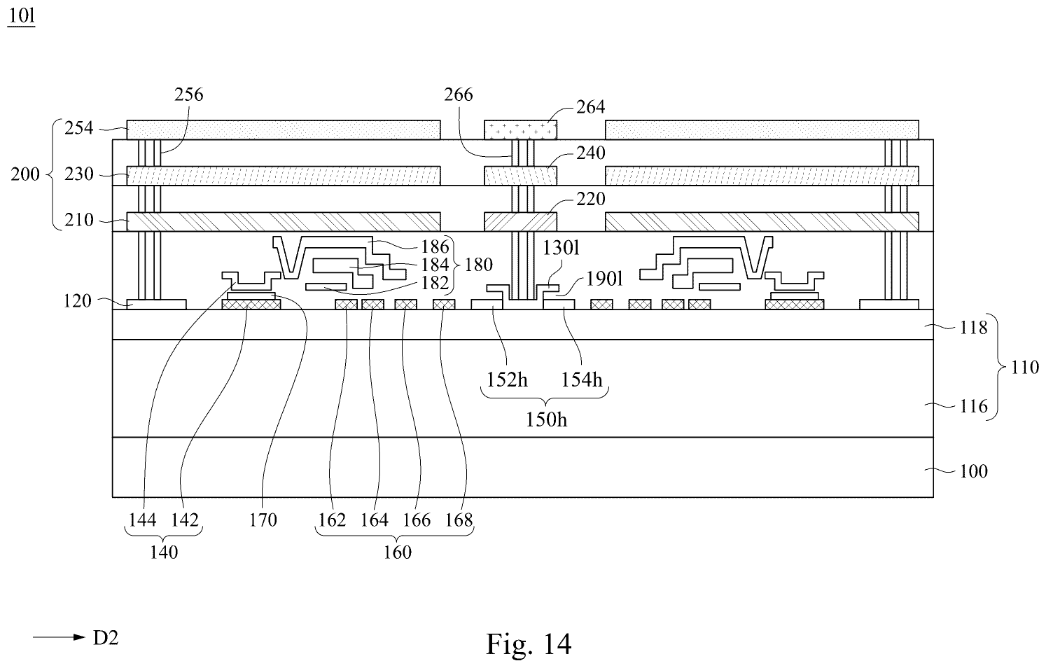

FIG. 14 is a cross-sectional view of a semiconductor device 10l according to one embodiment of the present disclosure. The semiconductor device 10l is similar to the semiconductor device 10h shown in FIG. 10, and the difference is that the semiconductor device 10l further includes insulating islands 190l disposed between the first P—GaN islands 150h and the drain electrodes 130l respectively. The insulating islands 190l partially surrounds the drain electrodes 130l. The insulating islands 190l is substantially connected with the dielectric layers 280. The insulating islands 190l can increase a voltage difference between the drain electrode 130l and the first P—GaN islands 150h, such that the hole injection quality can be enhanced. The semiconductor device 10l and the semiconductor device 10h shown in FIG. 10 have the same advantages, and therefore the description is not repeated hereinafter.

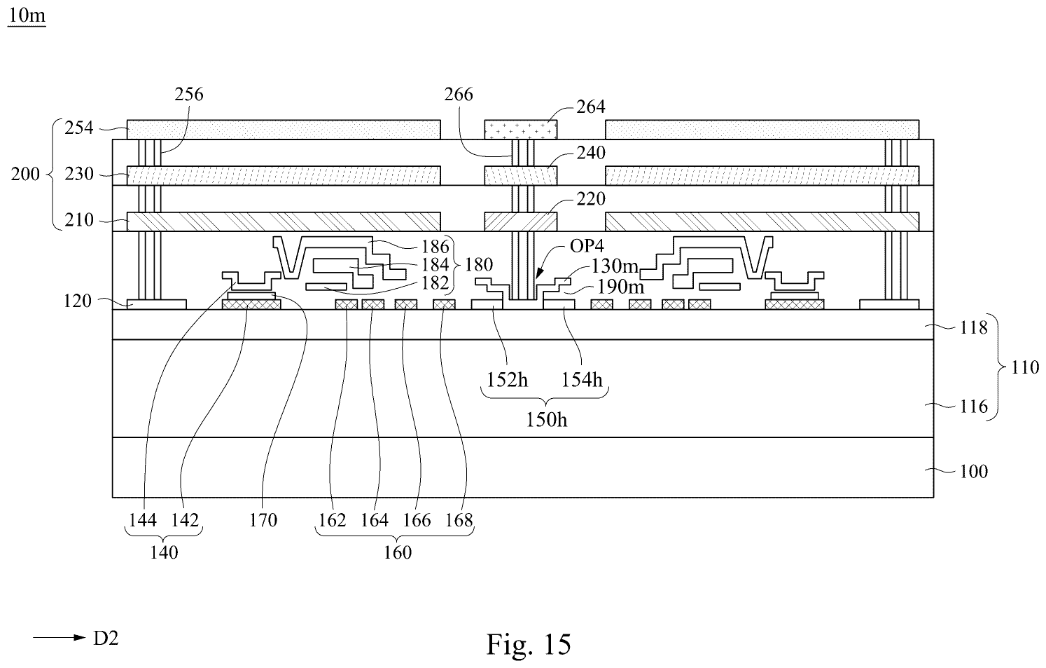

FIG. 15 is a cross-sectional view of a semiconductor device 10m according to one embodiment of the present disclosure. The semiconductor device 10m is similar to the semiconductor device 10l shown in FIG. 14, and the difference is that the insulating islands 190m in a cross-sectional view have a stepped shape, and the drain electrodes 130m in a cross-sectional view has a stepped shape. The distance between the drain electrodes 130m and the first P—GaN islands along the vertical direction is longer when the distance away from the opening OP4 is longer. That is, the thickness of the insulating islands 190m is thicker when the distance away from the opening OP4 is longer. The insulating islands 190m is substantially connected with the dielectric layer 280. In some embodiments, the stepped shape of the insulating islands 190m and the drain electrode 130m can be inclined steps. The semiconductor device 10l and the semiconductor device 10l shown in FIG. 14 have the same advantages, and therefore the description is not repeated hereinafter.

In summary, the first P—GaN islands are used as hole injection layers to absorb the trapped charges in the in the regions under and surrounding the drain electrode and at the interface between the first P—GaN islands and the underlying layer. The second P—GaN islands are used as hole injection layers to absorb the trapped charges in the in the regions under and surrounding field plates. The ohmic metal layers are used as hole injection layers to absorb the trapped charges in the in the regions under and surrounding gate electrode. Therefore, the semiconductor device of the present disclosure can reduce on-state resistance by disposing first P—GaN islands under the drain electrode, by disposing the second P—GaN islands under the field plates, and by disposing ohmic metal laeyrs between the gate P—GaN layer and the metal layer of the gate electrode. The insulating islands can increase a voltage difference between the drain electrode and the first P—GaN islands, such that the hole injection quality can be enhanced. When the first P—GaN islands includes a first portion and a second portion. The drain electrode is at least located between the first portion and the second portion and connects with the substrate. With such configuration, the ohmic metal of the drain electrode is electrically to the AlGaN or GaN material below the P—GaN islands. As such, the electrical current area is increased, and therefore the electrical resistance can be reduced.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

What is claimed is:

1. A semiconductor device, comprising:
an active layer having an active region;
a source electrode, a drain electrode, and a gate electrode disposed on the active region of the active layer and extending along a first direction;
a plurality of P—GaN islands disposed on the active region and under the drain electrode; and
a plurality of insulating islands disposed between the plurality of the P—GaN islands and the drain electrode.

2. The semiconductor device of claim 1, wherein the P—GaN islands are arranged along the first direction, and a sidewall of each of the P—GaN islands are surrounded by the drain electrode.

3. The semiconductor device of claim 1, wherein a length of each of the plurality of insulating islands along the first direction is shorter than a length of each of the plurality of P—GaN islands along the first direction.

4. The semiconductor device of claim 1, wherein a length of each of the plurality of insulating islands along the first direction is longer than a length of each of the plurality of P—GaN islands along the first direction.

5. The semiconductor device of claim 1, wherein the plurality of insulating islands have a stepped shape.

6. The semiconductor device of claim 1, wherein the drain electrode comprises an opening, and the plurality of insulating islands are exposed from the opening.

7. The semiconductor device of claim 6, wherein a length of the opening along the first direction is shorter than a length of each of the plurality of P—GaN islands along the first direction.

8. The semiconductor device of claim 6, wherein a length of the opening along the first direction is longer than a length of each of the plurality of P—GaN islands along the first direction.

9. The semiconductor device of claim 6, wherein a profile of the opening in a cross-sectional view has a stepped shape.

10. The semiconductor device of claim 1, wherein a length of each of the plurality of insulating islands along a second direction perpendicular to the first direction is shorter than a length of each of the plurality of P—GaN islands along the second direction.

11. A semiconductor device, comprising:
an active layer having an active region;
a source electrode, a drain electrode, and a gate electrode disposed on the active region of the active layer, wherein the source electrode, the drain electrode, and the gate electrode extend along a first direction; and
a plurality of P—GaN islands disposed on the active region and under the drain electrode, wherein each of the P—GaN islands comprises a first portion and a second portion, and the drain electrode is at least located between the first portion and the second portion of the plurality of P—GaN islands.

12. The semiconductor device of claim 11, wherein the first portion and the second portion of each of the plurality of P—GaN islands are partially connected to form an opening, and the drain electrode is at least located in the openings of the plurality of P—GaN islands.

13. The semiconductor device of claim 12, wherein the drain electrode is partially disposed above the plurality of P—GaN islands.

14. The semiconductor device of claim 13, wherein a length of each of the openings (OP4) along the first direction is shorter than a length of each of the plurality of P—GaN islands along the first direction.

15. The semiconductor device of claim 13, wherein a length of each of the openings (OP4) along the first direction is longer than a length of each of the plurality of P—GaN islands along the first direction.

16. The semiconductor device of claim 13, wherein a width of the drain electrode along a second direction perpendicular to the first direction is shorter than a width of each of the plurality of P—GaN islands along the second direction.

17. The semiconductor device of claim 13, wherein a width of the drain electrode along a second direction perpendicular to the first direction is longer than a width of each of the plurality of P—GaN islands along the second direction.

18. The semiconductor device of claim 13, further comprising:
a plurality of insulating islands disposed between the plurality of P—GaN islands and the drain electrode.

19. The semiconductor device of claim 18, wherein the plurality of insulating islands in a cross-sectional view have a stepped shape.

20. The semiconductor device of claim 19, wherein the drain electrode in a cross-sectional view has a stepped shape.

21. The semiconductor device of claim 13, wherein the first portion and the second portion of the plurality of P—GaN islands are spaced apart from each other.
